(19) United States
(12) Patent Application Publication
(10) Pub. No.: US 2005/0070074 A1
(43) Pub. Date: Mar. 31, 2005

(54) Method for dicing semiconductor wafer

(76) Inventor: Karl Heinz Priewasser, Muenchen (DE)

Correspondence Address: WENDEROTH, LIND & PONACK, L.L.P., 2033 K STREET N. W., SUITE 800, WASHINGTON, DC, 20006-1021, US

(21) Appl. No.: 10/947,241

(22) Filed: Sep. 23, 2004

(30) Foreign Application Priority Data
Sep. 25, 2003 (JP) 2003-333341

(51) Int. Cl. H01L 21/301

(52) U.S. Cl. 438/462

(57) ABSTRACT

To prevent scattering of minute triangular end-material fragments from the outer-peripheral end edge of the semiconductor wafer at both a dicing step and a grinding step not to lose recognizability of the information of the ID mark and discriminability of a notch formed for indicating the crystal orientation of the semiconductor wafer, a method for dicing a semiconductor wafer formed with semiconductor chips demarcated by streets includes: at least a groove formation step of cutting and forming grooves whose depth corresponds to a finish thickness of the semiconductor chips, along the streets leaving a slight outer peripheral region of the semiconductor wafer uncut, a protective-member disposition step of disposing a protective member on the front surface of the semiconductor wafer formed with the grooves, and a splitting step of grinding a back surface of the semiconductor wafer so as to expose the grooves, thereby dicing the semiconductor wafer into the individual semiconductor chips.

### BACKGROUND OF THE INVENTION

1. Field of the Invention

The present invention relates to a method for dicing a semiconductor wafer in which a semiconductor wafer formed with a plurality of semiconductor chips such as ICs or LSIs demarcated by streets, is previously cut along the streets by a dicing apparatus remaining the bottom uncut and is thereafter ground at its back surface by a grinding apparatus to separate the semiconductor into individual semiconductor chips.

2. Related Art

A semiconductor wafer of this type formed with a plurality of semiconductor chips such as ICs or LSIs is diced into the individual semiconductor chips by a cutting apparatus such as dicing apparatus, and the semiconductor chips are assembled and extensively utilized in the circuits of electric equipments such as portable telephones and personal computers.

In this regard, such electric equipments have been made smaller in size and lighter in weight. It is accordingly required to reduce the thickness of each semiconductor chip. A technique called “DBG” (Dicing Before Grinding) is known for reducing the thickness to or below 100 μm or 50 μm.

The DBG is a technique wherein a semiconductor wafer is diced into individual semiconductor chips in such a way that grooves whose depth corresponds to the finish thickness of the semiconductor chips are formed along streets formed in the front surface of the semiconductor wafer, that a protective member such as a tape is subsequently disposed on the front surface of the semiconductor wafer, and that the back surface of the semiconductor wafer is ground to expose the grooves to the back surface. Therefore, the technique has the following problems:

(1) In forming the grooves by a cutting blade along the streets formed in the front surface of the semiconductor wafer, minute triangular end-material fragments scatter from the outer periphery of the semiconductor wafer and are apprehended to damage the cutting blade. Further, the minute fragments having scattered drop onto a chuck table, and a semiconductor wafer to be subsequently worked is apprehended to damage when held on the chuck table.

(2) In a case where an ID mark indicating information items such as the thickness of the semiconductor chips, and the interval and width of the streets, is formed on the outer peripheral region of the semiconductor wafer, the information items cannot be recognized if the grooves are formed in the ID mark by the cutting blade.

(3) When the back surface of the semiconductor wafer is being ground, a polluted grinding liquid is apprehended to permeate from the outer periphery of the semiconductor wafer into the cut grooves and to pollute the semiconductor chips.

(4) When the back surface of the semiconductor wafer is being ground, minute triangular end-material fragments appear and scatter from a plurality of places at the outer periphery of the semiconductor wafer. It is therefore apprehended that a notch indicating the crystal orientation of the semiconductor wafer will become indiscernible from the places, and that operations at succeeding steps will be hampered.

There has also been known a technique that inner part of the semiconductor wafer at which the semiconductor chips are formed is subjected to dicing in a state where the peripheral part of the wafer is left uncut (refer to JP-A-2002-43254). The known technique employs a dicing apparatus including means for sensing the outer ends of the semiconductor wafer. The data of the outer ends of the wafer as sensed by the sensing means are stored. On the basis of the stored data, cutting is started at a predetermined distance inside one of the outer ends along each dicing line and is ended at a predetermined distance inside the other outer end. Thus, at the outer peripheral part of the wafer extending to the predetermined distances from the respective outer ends, the wafer is left at least partially in its thickness direction. The part of the wafer inside the outer peripheral part is subjected to “full dicing”. It is claimed that, since fragments are not separated by the cutting, the semiconductor chips or the blade can be prevented from damaging.

The semiconductor wafer applied to the known dicing technique has an orientation flag indicating the crystal orientation of this wafer. Besides, the semiconductor wafer is subjected to the full dicing in a state where it is fixed to a ring-shaped frame through a dicing tape, and where the dicing tape is attracted to a cutting table by suction together with the frame. In the full dicing, the fragments are really prevented from separating and scattering from the outer peripheral part. However, in a case where the semiconductor wafer is formed to the finish thickness of the semiconductor chips, for example, 50 μm or below from the beginning, it entirely flexes at a circuit formation step for the semiconductor chips because it is too thin. Accordingly, the processing of the wafer (coating with a photoresist, removal thereof by washing, etc.) and the handling thereof (drying and transportation of the wafer, etc.) are seriously hampered.

Besides, the part not subjected to the dicing remains at the outer peripheral part of the wafer after the full dicing. In this regard, it will be possible to mount a protective member on the front surface side of the wafer for the purpose of grinding the back surface side of the wafer and thinning the wafer still further. Since, however, the semiconductor chip parts have already been individuated, it is difficult to grind the wafer with a grindstone touching the back surface thereof, in the individuated state of the semiconductor chips.

### SUMMARY OF THE INVENTION

An object of the present invention is to provide a method for dicing a semiconductor wafer formed with semiconductor chips demarcated by streets, in which, in splitting the semiconductor wafer into the individual semiconductor chips, triangular fragments are prevented from separating and scattering from the outer peripheral edge of the semiconductor wafer at both a dicing step and a grinding step, so that a cutting blade and a semiconductor wafer to be subsequently worked are not apprehended to damage.

A method for dicing a semiconductor wafer according to the invention consists in a method for dicing a semiconductor wafer in which the semiconductor wafer formed in its front surface with a plurality of semiconductor chips demarcated by streets is diced into individual semiconductor chips, which comprises at least a groove formation step of cutting and forming grooves whose depth corresponds to a finish thickness of the semiconductor chips, along the streets in a state where the outer peripheral region of the semiconductor wafer is slightly left uncut; a protective-member disposition step of disposing a protective member on the front surface of the semiconductor wafer formed with the grooves; and a splitting step of grinding the back surface of the semiconductor wafer so as to expose the grooves, thereby dicing the semiconductor wafer into the individual semiconductor chips.

In a preferable aspect of performance of the invention, at least an ID mark is formed at a predetermined position of the outer peripheral region of the semiconductor wafer; and the grooves are formed avoiding the ID mark at the groove formation step.

In the method for dicing the semiconductor wafer according to the invention, the grooves to be cut along the streets are formed in the state where the outer peripheral region of the semiconductor wafer is slightly left uncut, and hence, the cut grooves do not extend to the outer-peripheral end edge of the semiconductor wafer. Therefore, at the subsequent splitting step at which the back surface of the semiconductor wafer is ground while a grinding liquid is being fed, the polluted grinding liquid is not apprehended to permeate from the outer-peripheral end edge into the cut grooves and to pollute the semiconductor chips. Moreover, the ID mark formed on the outer peripheral region is not damaged, so that the recognizability of the information of the ID mark is not lost. Furthermore, minute triangular end-material fragments do not scatter from the outer-peripheral end edge of the semiconductor wafer, so that the discriminability of a notch formed for indicating the crystal orientation of the semiconductor wafer is not lost.

### BRIEF DESCRIPTION OF THE DRAWING

FIG. 1 is a perspective view showing a dicing apparatus to be used in a method for dicing a semiconductor wafer according to a practicable embodiment of the present invention;

FIG. 2 is a perspective view showing the semiconductor wafer to be applied to the splitting in the embodiment;

FIG. 3 is a perspective view showing the semiconductor wafer subjected to a groove cutting step by a dicing apparatus in the embodiment;

FIG. 4 is a perspective view showing the back surface side of the semiconductor wafer in the state where a protective member has been disposed on the groove cutting surface of this wafer after the groove cutting step in the embodiment;

FIG. 5 is a perspective view showing only the essential portions of a grinding apparatus to be used for the method for dicing the semiconductor wafer according to the embodiment;

FIG. 6 is a perspective view showing the semiconductor wafer in the state where the back surface side of this wafer has been ground by the grinding apparatus in the embodiment so as to expose cut grooves;

FIG. 7 is a perspective view showing the inverted state of the semiconductor wafer whose back surface side has been ground in the embodiment so as to expose the cut grooves; and

FIG. 8 is a perspective view showing the inverted semiconductor wafer mounted on a dicing frame and the protective member is torn off therefrom.

### DETAILED DESCRIPTION OF PREFERRED EMBODIMENT

According to the present invention, a semiconductor wafer is formed to such a thickness as does not hamper a circuit formation step for semiconductor chips and the later handling of the semiconductor wafer, cut grooves whose depth corresponds to the finish thickness of the semiconductor chips are formed along streets demarcating the semiconductor chips, in a state where the outer peripheral region of the semiconductor wafer is slightly left uncut, and the back surface of the semiconductor wafer is ground until the cut grooves formed from the front surface side of the semiconductor wafer are exposed to the back surface side of this wafer. Thus, the semiconductor chips formed in the semiconductor wafer are individuated, whereby the semiconductor chips of predetermined thin structure can be formed. Moreover, in a case where a notch indicating the crystal orientation of the semiconductor wafer and an ID mark indicating the state of this wafer are respectively formed at the outer-peripheral end edge of the semiconductor wafer and on the outer peripheral region thereof beforehand, neither the discriminability of the crystal orientation nor the recognizability of the information of the ID mark is lost in splitting the semiconductor wafer into the thin semiconductor chips, at the dicing step and the grinding step, whereby the semiconductor wafer can be efficiently diced into the semiconductor chips.

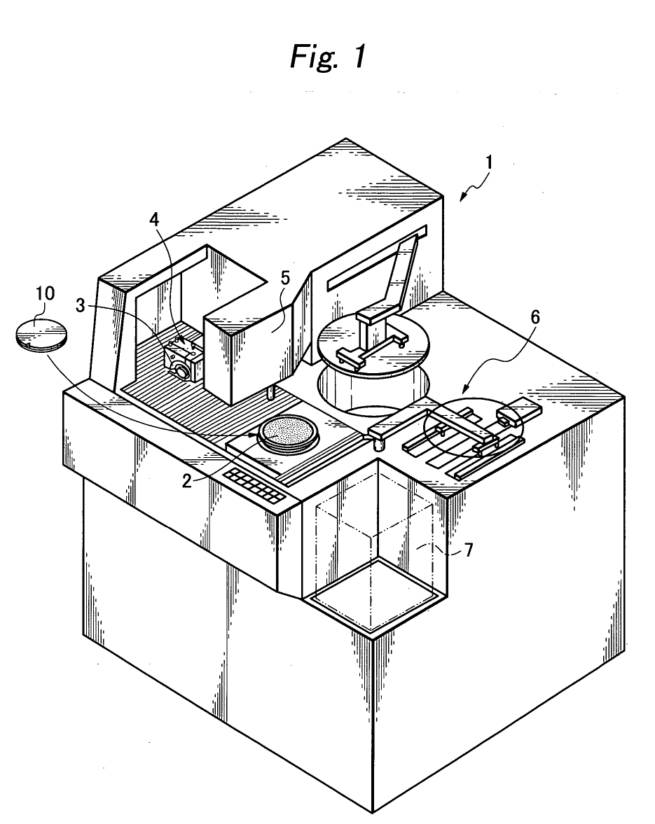

A method for dicing a semiconductor wafer according to the invention will be described with reference to the drawings. FIG. 1 is a perspective view showing an example of a dicing apparatus for use in the dicing method. The dicing apparatus 1 includes, at least, a chuck table 2 on which the semiconductor wafer 10 is put, cutting means 4 having a blade 3 for cutting the put semiconductor wafer 10, alignment means 5 to detect the state of the semiconductor wafer 10, that is, the size of the wafer 10, the size of each semiconductor chip formed in the front surface of the wafer, the state of streets formed in the wafer, etc., and supply means 6 to supply the semiconductor wafer 10 to the chuck table 2. Incidentally, pluralities of such semiconductor wafers are accommodated in a cassette 7, which is set at an appropriate position in the dicing apparatus 1.

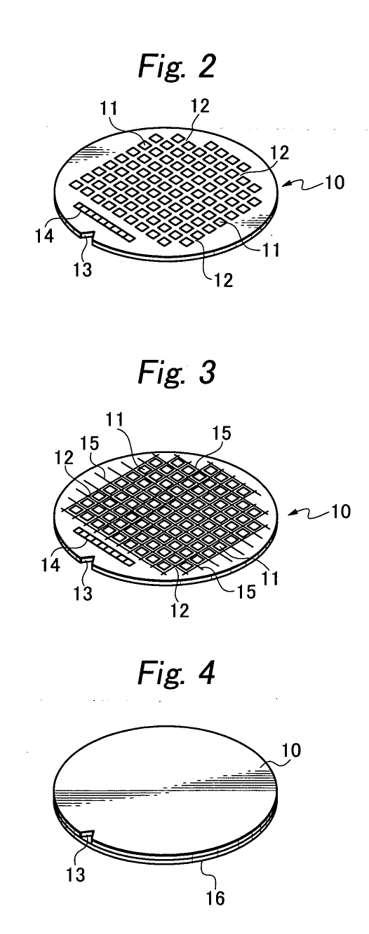

FIG. 2 shows the semiconductor wafer 10 to be diced in this embodiment. The semiconductor wafer 10 is formed with a plurality of semiconductor chips 11 which are aligned on the front surface side of this wafer, and which are demarcated by the streets 12. A notch 13 to indicate the crystal orientation of the wafer 10 is formed at the end edge of the wafer, and an ID mark 14 is provided in the vicinity of the notch 13.

The aspect or state of the semiconductor wafer 10 is recorded in the ID mark 14 in this case. This aspect or state contains, for example, the size of the wafer 10, the sort, size and finish thickness of the semiconductor chip 11, and the state (width and interval) of the vertical and horizontal streets 12. The semiconductor wafer 10 can be appropriately cut or ground in conformity with preset steps by reading the ID mark 14.

As the first step of the dicing method, the semiconductor wafer 10 put on the chuck table 2 of the dicing apparatus 1 is detected the positions of the streets 12 by the alignment means 5. And then grooves 15 having a depth corresponding to the finish thickness of the semiconductor chips 11 are formed by cutting along the streets 12 in a cutting region with the blade 3 of the cutting means 4, leaving the slight outer peripheral region of the semiconductor wafer 10 uncut, as shown in FIG. 3.

More specifically, if the final finish thickness of the semiconductor chips 11 is, for example, 100 μm, the grooves 15 are formed to be 100-105 μdeep, and if it is 50 μm, they are formed to be 50-55 μm deep. As a matter of course, the thickness of the semiconductor wafer 10 is larger than the depth of the grooves 15 to be formed, and it is nearly double the depth by way of example. In short, the cutting formation of the grooves 15 is so-called “half cut” in which the outer peripheral part of the semiconductor wafer 10 is left uncut. Accordingly, even after the grooves 15 have been formed, the wafer 10 does not easily break. Besides, the ID mark 14 is not cut, so that the recognizability of information is not lost. Incidentally, the blade 3 for use in the cutting should preferably have a small diameter, for example, about 1-2 inches.

After the step of forming the grooves 15 has ended in this manner, a protective member 16 made of a protective tape having an adhesive agent is stuck and disposed on the front surface side of the semiconductor wafer 10 formed with the grooves 15, as shown in FIG. 4. The adhesive agent for use in this case should preferably be of ultraviolet (UV) irradiation type in order that its adhesive component may be prevented from remaining on the front surface of the semiconductor wafer 10 at a later tearing-off step. The semiconductor wafer 10 on which the protective member 16 has been disposed, is transferred to the next splitting step.

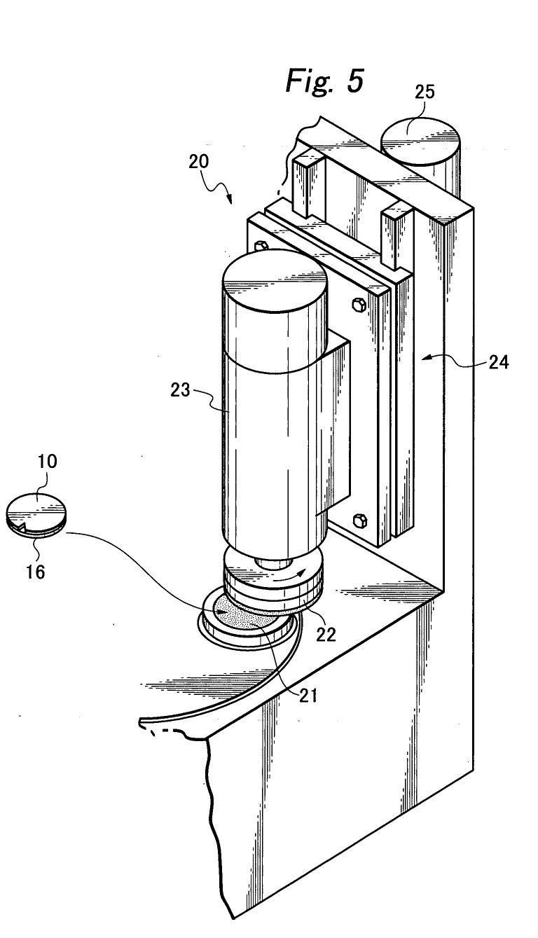

The splitting step is performed by a grinding apparatus 20 as shown in FIG. 5 in this example. The grinding apparatus 20 includes, at least, a chuck table 21, a grindstone 22, a drive unit 23 to drive the grindstone 22, a guide unit 24 to support the drive unit 23 and guides the movement thereof in a vertical direction, and a moving drive unit 25 to precisely move the drive unit 23 in the vertical direction.

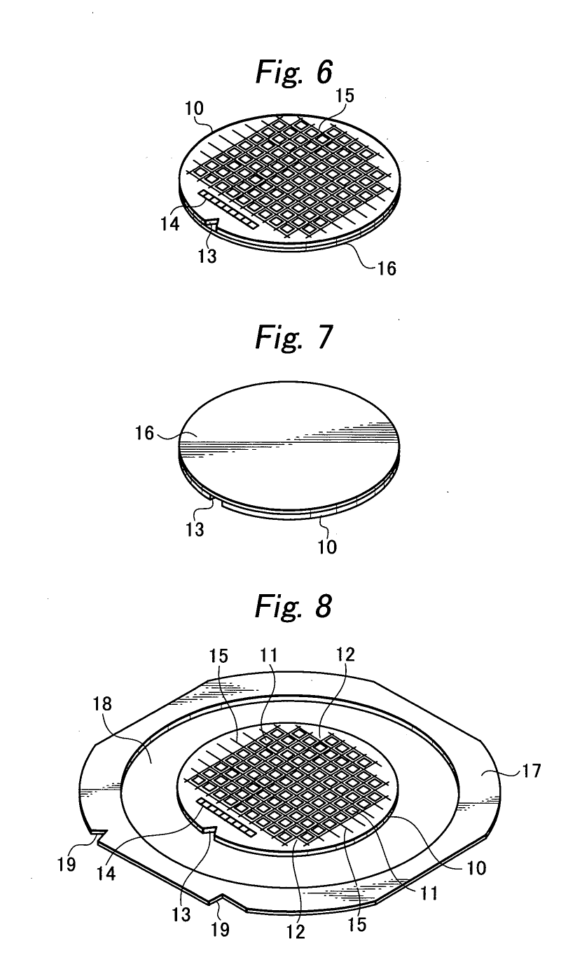

Herein, the semiconductor wafer 10 on which the protective member 16 has been disposed is turned over to locate its back surface upward, and it is put on and fixed to the chuck table 21 with the protective member 16 touching this chuck table. Subsequently, the back surface side of the semiconductor wafer 10 is ground by driving the grindstone 22 while a grinding liquid is being fed. Thus, the whole back surface side is homogeneously ground until the grooves 15 cut and formed from the front surface side are exposed as shown in FIG. 6.

When the back surface side of the semiconductor wafer 10 has been ground in this manner, the semiconductor chips 11 formed on the front surface side of the semiconductor wafer 10 are respectively individuated. Moreover, the individuated semiconductor chips 11 have a thickness corresponding to the depth of the grooves 15, that is, the finish thickness.

At the splitting step, the back surface side of the semiconductor wafer 10 is ground by the grindstone 22 while the grinding liquid is being fed. Since, however, the grooves 15 formed along the streets 12 do not extend to the outer-peripheral end edge of the semiconductor wafer 10, the polluted grinding liquid is not apprehended to permeate from the outer-peripheral end edge of the semiconductor wafer 10 to the interior thereof and to pollute the semiconductor chips 11. Moreover, minute triangular end-material fragments are not apprehended to appear from the outer-peripheral end edge of the semiconductor wafer 10, and the discriminability of the notch 13 indicating the crystal orientation is not spoilt.

After the end of the splitting step, the resulting semiconductor wafer 10 is picked up from the grinding apparatus 20. Subsequently, as shown in FIG. 7, the ground back surface side is turned down to locate the protective member 16 upward, and the semiconductor wafer 10 is brought into an appropriate direction on the basis of the notch 13 indicating the crystal orientation. Further, as seen from FIG. 8, the semiconductor wafer 10 is stuck on a frame 17 called “dicing frame”, through an extensible tape 18 called “dicing tape”, and the protective member 16 is torn off. Incidentally, the frame 17 is provided with locating cut-away parts 19 to indicate the crystal orientation of the stuck semiconductor wafer 10, and various subsequent operations are smoothly performed by the cut-away parts 19 conjointly with the information of the ID mark 14.

With a method for dicing a semiconductor wafer according to the invention, in a case where a semiconductor wafer is formed to such a thickness as does not hamper a circuit formation step for semiconductor chips and the later handling of the semiconductor wafer and where the semiconductor wafer is cut along streets demarcating the semiconductor chips, by a dicing apparatus, cut grooves whose depth corresponds to the finish thickness of the semiconductor chips are formed in a state where the outer peripheral region of the semiconductor wafer is slightly left uncut, whereupon the back surface of the semiconductor wafer is ground until the cut grooves are exposed to the back surfaceside of the semiconductor wafer. Thus, the semiconductor wafer is diced into the individual semiconductor chips, whereby the semiconductor chips of predetermined thin structure can be formed. Moreover, neither the information recognizability of an ID mark formed on the outer peripheral region of the semiconductor wafer, nor the discriminability of a notch indicating the crystal orientation of the semiconductor wafer and formed at the outer-peripheral end edge of this wafer is lost at the dicing step and the grinding step, whereby the semiconductor wafer can be efficiently diced into the thin-structured semiconductor chips. Therefore, the dicing method can be extensively utilized for the fabrication of small-sized and thin-structured semiconductor chips.

1. A method for dicing a semiconductor wafer in which the semiconductor wafer formed in its front surface with a plurality of semiconductor chips demarcated by streets is diced into individual semiconductor chips, comprising at least:
a groove formation step of cutting and forming grooves whose depth corresponds to a finish thickness of the semiconductor chips, along the streets in a state where an outer peripheral region of the semiconductor wafer is slightly left uncut;
a protective-member disposition step of disposing a protective member on the front surface of the semiconductor wafer formed with the grooves; and
a splitting step of grinding the back surface of the semiconductor wafer so as to expose the grooves, thereby dicing the semiconductor wafer into the individual semiconductor chips.

2. A method for dicing a semiconductor wafer according to claim 1, wherein at least an ID mark is formed at a predetermined position of the outer peripheral region of the semiconductor wafer; and the grooves are formed avoiding the ID mark at said groove formation step.
